(19) United States
(12) Patent Application Publication
(10) Pub. No.: US 2026/0198299 A1
(43) Pub. Date: Jul. 9, 2026

(54) INTERCONNECTION STRUCTURE, AND METHOD FOR FABRICATING THE SAME

(71) Applicant: TAIWAN SEMICONDUCTOR MANUFACTURING COMPANY, LTD., Hsinchu (TW)

(72) Inventors: Chin-Lung CHUNG, Hsinchu (TW); Shin-Yi YANG, Hsinchu (TW); Tsu-Chun KUO, Hsinchu (TW)

(73) Assignee: TAIWAN SEMICONDUCTOR MANUFACTURING COMPANY, LTD., Hsinchu (TW)

(21) Appl. No.: 19/011,239

(22) Filed: Jan. 6, 2025

(51) Int. Cl. H01L 23/532; H01L 21/768; H01L 23/522

(52) U.S. Cl. CPC H10W 20/4432; H10W 20/057; H10W 20/42; H10W 20/4441

(57) ABSTRACT

A method is provided for fabricating an interconnection structure. A first metal feature and a first dielectric layer surrounding the first metal feature are formed on a semiconductor substrate. A second metal feature is formed to be aligned with and cover the first metal feature. The second metal feature is different from the first metal feature in terms of materials. A second dielectric layer is deposited over the first dielectric layer and the second metal feature. A trench is formed in the second dielectric layer to reveal the second metal feature. A metal line is formed in the trench.

### BACKGROUND

The semiconductor integrated circuit (IC) industry has over the past decades experienced tremendous advancements and is still experiencing vigorous development. However, advances in IC design need to be accompanied by improvements in manufacturing in order to optimize device performance. As an example, interconnections between different layers of wires and associated dielectrics affect IC performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a sectional view illustrating an interconnection structure in accordance with a first embodiment.

FIGS. 2 and 3 are sectional views respectively illustrating an X-cut section and a Y-cut section of an interconnection structure in accordance with a second embodiment.

FIG. 4 is a flow chart illustrating a method for fabricating the interconnection structure in accordance with the second embodiment.

FIGS. 5 through 10 are sectional views illustrating some intermediate structures formed during the fabrication of the interconnection structure in accordance with the second embodiment.

FIGS. 11 and 12 are sectional views respectively illustrating an X-cut section and a Y-cut section of an interconnection structure in accordance with a third embodiment.

FIG. 13 is a flow chart illustrating a method for fabricating the interconnection structure in accordance with the third embodiment.

FIGS. 14 through 19 are sectional views illustrating some intermediate structures formed during the fabrication of the interconnection structure in accordance with the third embodiment.

FIGS. 20 and 21 are sectional views respectively illustrating an X-cut section and a Y-cut section of an interconnection structure in accordance with a fourth embodiment.

FIG. 22 is a flow chart illustrating a method for fabricating the interconnection structure in accordance with the fourth embodiment.

FIGS. 23 through 25 are sectional views illustrating some intermediate structures formed during the fabrication of the interconnection structure in accordance with the fourth embodiment.

FIGS. 26 and 27 are sectional views respectively illustrating an X-cut section and a Y-cut section of an interconnection structure in accordance with a fifth embodiment.

FIG. 28 is a flow chart illustrating a method for fabricating the interconnection structure in accordance with the fifth embodiment.

FIGS. 29 through 31 are sectional views illustrating some intermediate structures formed during the fabrication of the interconnection structure in accordance with the fifth embodiment.

FIGS. 32 and 33 are sectional views respectively illustrating an X-cut section and a Y-cut section of an interconnection structure in accordance with a sixth embodiment.

FIG. 34 is a flow chart illustrating a method for fabricating the interconnection structure in accordance with the sixth embodiment.

FIGS. 35 and 36 are sectional views illustrating some intermediate structures formed during the fabrication of the interconnection structure in accordance with the sixth embodiment.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

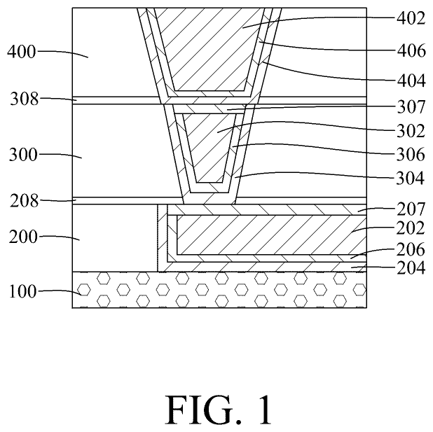

FIG. 1 illustrates a sectional view of an interconnection structure formed over a semiconductor substrate 100 in accordance with a first embodiment. The semiconductor substrate 100 may be a bulk semiconductor substrate or a semiconductor-on-insulator (SOI) substrate, which may be doped (e.g., with a p-type or an n-type dopant) or undoped. In some embodiments, an SOI substrate includes a layer of a semiconductor material formed on an insulator layer. The insulator layer may be a buried oxide (BOX) layer, a silicon oxide layer or any other suitable layer. The insulator layer may be provided on a suitable substrate, such as silicon, glass or the like. The semiconductor substrate 100 may be made of a suitable semiconductor material, such as silicon or the like. In some embodiments, the semiconductor substrate 100 is a silicon wafer; and in other embodiments, the semiconductor substrate 100 is made of a compound semiconductor such as silicon carbide, gallium arsenide, indium arsenide, indium phosphide or other suitable materials. In still other embodiments, the semiconductor substrate 100 is made of an alloy semiconductor such as GaAsP, AlInAs, AlGaAs, GaInAs, GaInP, GaInAsP or other suitable materials.

In some embodiments, the semiconductor substrate 100 includes various p-type doped regions and/or n-type doped regions, such as p-type wells, n-type wells, p-type source/drain features and/or n-type source/drain features (source/drain feature(s) may refer to a source or a drain, individually or collectively depending upon the context), formed by a suitable process such as ion implantation, thermal diffusion, a combination thereof, or the like. In some embodiments, the semiconductor substrate 100 may include other functional elements such as resistors, capacitors, diodes, transistors, and/or the like. The transistors are, for example, field effect transistors (FETs), such as planar FETs and/or 3D FETs (e.g., FinFETs, GAAFETs). The semiconductor substrate 100 may include lateral isolation features (e.g., shallow trench isolation (STI)) configured to separate various functional elements formed on and/or in the semiconductor substrate 100. In some embodiments, the semiconductor substrate 100 includes some connection features, such as metal vias, metal lines, etc., which are connected to some of the functional elements.

In the illustrative embodiment, the interconnection structure includes multiple interconnection layers, where a metal line 202 is formed in a first interconnection layer, a metal via 302 is formed in a second interconnection layer, and a metal line 402 is formed in a third interconnection layer, and the metal line 402 is electrically connected to the metal line 202 through the metal via 302. In addition to the metal line 202, the first interconnection layer further includes a dielectric layer 200, a conductive barrier layer 204, a conductive liner layer 206, and a conductive cap layer 207. The metal line 202 extends laterally, and is disposed in and surrounded by the dielectric layer 200. The conductive barrier layer 204 is disposed between the metal line 202 and the dielectric layer 200 for blocking metal elements in the metal line 202 from diffusing into the dielectric layer 200, thereby promoting device reliability in terms of, for example, time-dependent dielectric breakdown (TDDB). The conductive barrier layer 204 extends along side surfaces and a bottom surface of the metal line 202. The conductive liner layer 206 extends along the side surfaces and the bottom surface of the metal line 202 between the metal line 202 and the conductive barrier layer 204 to provide good adhesion of the metal line 202 to the conductive barrier layer 204, thereby promoting device reliability in terms of, for example, electromigration performance. The conductive cap layer 207 is disposed on top of the metal line 202 for enhancing adhesion of the metal line 202 to an overlying conductive feature that is to be formed later. In accordance with some embodiments, the metal line 202 may include, for example, Cu, W, Mo, Co, Ru, alloys (e.g., MoW, CuAl, CuZn, etc.), other suitable conductive materials, or any combination thereof, and may be formed using, for example, a single damascene process, a metal-first process, other suitable processes, or any combination thereof. In some embodiments, the metal line 202 is made of Cu. In accordance with some embodiments, the dielectric layer 200 may include, for example, SiOₓ, low-k materials (e.g., SiCOH), other suitable materials, or any combination thereof. In accordance with some embodiments, the conductive barrier layer 204 may include, for example, Ta, TaN, Ti, TiN, other suitable materials, or any combination thereof. In some embodiments, metal nitride (e.g., TaN, TiN) may have better ability than a pure metal (e.g., Ta, Ti) in blocking the diffusion of metal elements (e.g., Cu). In accordance with some embodiments, the conductive liner layer 206 may include, for example, Co, Ru, RuCo, other suitable materials, or any combination thereof. In some embodiments, RuCo may provide good gap-fill during the process of forming the metal line 202 when the width of the metal line 202 is small and/or the aspect ratio of the metal line 202 is high. In accordance with some embodiments, the conductive cap layer 207 may include, for example, Co, Ru, RuCo, other suitable materials, or any combination thereof. The conductive cap layer 207 may include either the same material as the conductive liner layer 206 or different materials. An etch stop layer 208 is disposed over the dielectric layer 200. In accordance with some embodiments, the etch stop layer 208 may have a single-layer structure or a multi-layer structure, and may include, for example, elements such as Al, Si, O, C, N, other suitable elements, or any combination thereof (e.g., AlNₓ, AlON, AlOₓ, AlOC, AlOCN, etc.).

In addition to the metal via 302, the second interconnection layer further includes a dielectric layer 300, a conductive barrier layer 304, a conductive liner layer 306, and a conductive cap layer 307. The metal via 302 extends vertically, and is disposed in and surrounded by the dielectric layer 300. The conductive barrier layer 304 is disposed between the metal via 302 and the dielectric layer 300 for blocking metal elements in the metal via 302 from diffusing into the dielectric layer 300. The conductive barrier layer 304 extends along side surfaces and a bottom surface of the metal via 302, with its bottom portion being disposed on the conductive cap layer 207. The conductive liner layer 306 extends along the side surfaces and the bottom surface of the metal via 302 between the metal via 302 and the conductive barrier layer 304 to provide good adhesion of the metal via 302 to the conductive barrier layer 304. The conductive cap layer 307 is disposed on top of the metal via 302 for enhancing adhesion of the metal via 302 to an overlying conductive feature that is to be formed later. In accordance with some embodiments, the metal via 302 may include, for example, Cu, W, Mo, Co, Ru, alloys (e.g., MoW, CuAl, CuZn, etc.), other suitable conductive materials, or any combination thereof, and may be formed using, for example, a single damascene process, a metal-first process, other suitable processes, or any combination thereof. In some embodiments, the metal via 302 is made of Cu. In accordance with some embodiments, the dielectric layer 300 may include, for example, SiOₓ, low-k materials (e.g., SiCOH), other suitable materials, or any combination thereof. In accordance with some embodiments, the conductive barrier layer 304 may include, for example, Ta, TaN, Ti, TiN, other suitable materials, or any combination thereof. In accordance with some embodiments, the conductive liner layer 306 may include, for example, Co, Ru, RuCo, other suitable materials, or any combination thereof. In accordance with some embodiments, the conductive cap layer 307 may include, for example, Co, Ru, RuCo, other suitable materials, or any combination thereof. The conductive cap layer 307 may include either the same material as the conductive liner layer 306 or different materials. An etch stop layer 308 is disposed over the dielectric layer 300. In accordance with some embodiments, the etch stop layer 308 may have a single-layer structure or a multi-layer structure, and may include, for example, elements such as Al, Si, O, C, N, other suitable elements, or any combination thereof (e.g., AlN, AlON, AlOₓ, AlOC, AlOCN, etc.).

In addition to the metal line 402, the third interconnection layer further includes a dielectric layer 400, a conductive barrier layer 404, and a conductive liner layer 406. The metal line 402 extends laterally, and is disposed in and surrounded by the dielectric layer 400. The conductive barrier layer 404 is disposed between the metal line 402 and the dielectric layer 400 for blocking metal elements in the metal line 402 from diffusing into the dielectric layer 400. The conductive barrier layer 404 extends along side surfaces and a bottom surface of the metal line 402, with its bottom portion being disposed on the conductive cap layer 307. The conductive liner layer 406 extends along the side surfaces and the bottom surface of the metal line 402 between the metal line 402 and the conductive barrier layer 404 to provide good adhesion of the metal line 402 to the conductive barrier layer 404. A conductive cap layer may be disposed on top of the metal line 402, but is not shown in FIG. 1. In accordance with some embodiments, the metal line 402 may include, for example, Cu, W, Mo, Co, Ru, alloys (e.g., MoW, CuAl, CuZn, etc.), other suitable conductive materials, or any combination thereof, and may be formed using, for example, a single damascene process, a metal-first process, other suitable processes, or any combination thereof. In some embodiments, the metal line 402 is made of Cu. In accordance with some embodiments, the dielectric layer 400 may include, for example, SiOₓ, low-k materials (e.g., SiCOH), other suitable materials, or any combination thereof. In accordance with some embodiments, the conductive barrier layer 404 may include, for example, Ta, TaN, Ti, TiN, other suitable materials, or any combination thereof. In accordance with some embodiments, the conductive liner layer 406 may include, for example, Co, Ru, RuCo, other suitable materials, or any combination thereof.

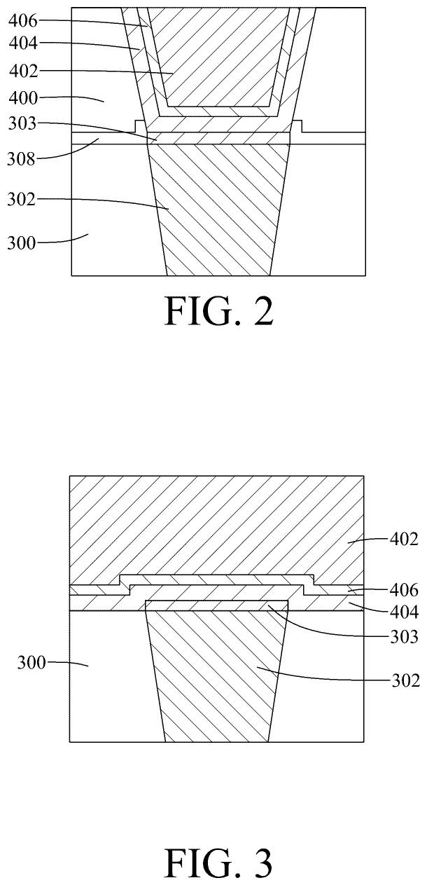

FIGS. 2 and 3 are sectional views respectively illustrating an X-cut section and a Y-cut section of an interconnection structure in accordance with a second embodiment, which is similar to the first embodiment. It is noted that the semiconductor substrate 100 and the first interconnection layer of the first embodiment (see FIG. 1) are omitted in FIGS. 2 and 3 in order to focus on differences between the first embodiment and the second embodiment. In the second embodiment, the metal via 302 is different from the metal line 402 in terms of materials, and includes, for example, Mo, Ru, MoW, other suitable materials (e.g., metals, alloys, etc.), or any combination thereof. Since Mo, Ru and MoW have characteristics such as small grain boundary reflection and/or short mean free paths, shrinking the dimension of metal vias would not cause a significant increase in their resistivity. Accordingly, Mo, Ru or MoW would be a good option to be used in metal vias and/or metal lines in accordance with some embodiments to provide low resistance while adhering to small device dimensions. In addition, since Mo and Ru are not prone to metal diffusion, the metal via 302 can be directly formed on the dielectric layer 300 when Mo and/or Ru is used to form the metal via 302, without the need to form a barrier layer and/or a liner layer (e.g., the conductive barrier layer 304 and the conductive liner layer 306 in FIG. 1) between the metal via 302 and the dielectric layer 300. A metal cap 303 is formed on top of the metal via 302, has a bottom surface completely disposed on the metal via 302, and is configured to separate the metal via 302 from the conductive barrier layer 404, thereby preventing formation of metal nitride during subsequent processes when the conductive barrier layer 404 includes nitrogen (e.g., TaN, TiN, and so on). Metal nitrides, such as molybdenum nitride (MoNₓ) or ruthenium nitride (RuNₓ), may increase overall resistance between the metal line 402 and the metal via 302. In accordance with some embodiments, the metal cap 303 has a resistivity smaller than a resistivity of a metal nitride material that includes a metal element which is also included in the metal via 302, so the overall resistance between the metal line 402 and the metal via 302, equaling a sum of resistances of the conductive liner layer 406, the conductive barrier layer 404, an interface between the conductive barrier layer 404 and the metal cap 303, and the metal cap 303, would be smaller than an overall resistance when metal nitride is formed at an interface between the conductive barrier layer 404 and the metal via 302 due to a direct contact therebetween. In accordance with some embodiments, the metal cap 303 may include, for example, W, Cu, CuAl, CuZn, other suitable materials (e.g., metals, alloys, etc.), or any combination thereof. These materials are not prone to react with nitrogen in the conductive barrier layer 404 to form metal nitride under the temperature conditions of the subsequent processes, which are usually lower than 400° C. In accordance with some embodiments, the metal cap 303 is thinner than the metal via 302, and may have a thickness in a range from about 5 angstroms to about 30 angstroms, thereby effectively separating the metal via 302 from the conductive barrier layer 404, while minimizing increase of resistance resulting from the metal cap 303.

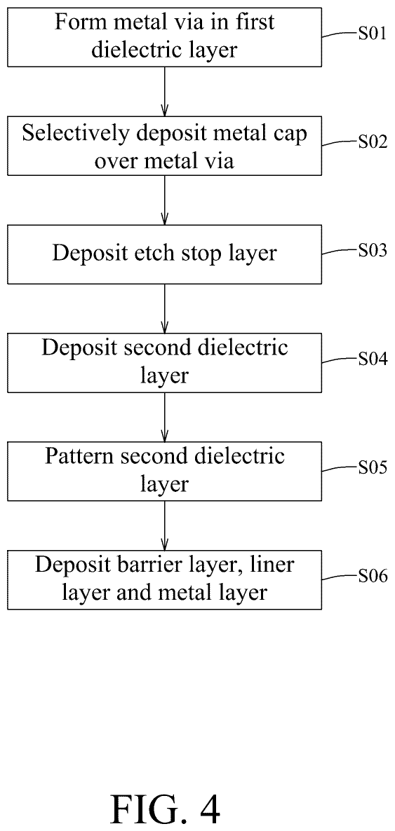

FIG. 4 is a flow chart illustrating a method for fabricating the interconnection structure in accordance with the second embodiment.

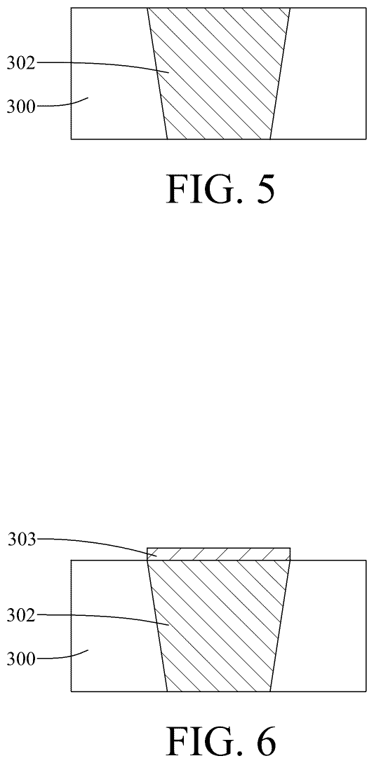

Referring to FIGS. 4 and 5, in step S01, a dielectric layer 300 and a metal via 302 are formed over a semiconductor substrate (not shown), and the dielectric layer 300 surrounds the metal via 302. In accordance with some embodiments, the metal via 302 may be connected to a conductive component (e.g., the metal line 202 or the conductive cap layer 207 in FIG. 1) underlying the dielectric layer 300, and extend in an upward direction. In accordance with some embodiments, the metal via 302 may be formed using, for example, a single damascene process, a metal-first process, other suitable processes, or any combination thereof. In accordance with some embodiments, the metal via 302 may be deposited using, for example, chemical vapor deposition (CVD), atomic layer deposition (ALD), physical vapor deposition (PVD), electrochemical plating (ECP), electroless plating, other suitable techniques, or any combination thereof. In accordance with some embodiments, the metal via 302 is formed under a process temperature ranging from room temperature to about 400° C. In accordance with some embodiments, the dielectric layer 300 may be formed using, for example, PVD, CVD, plasma-enhanced CVD (PECVD), other suitable techniques, or any combination thereof.

Referring to FIGS. 4 and 6, in step S02, a metal cap 303 is selectively deposited on the metal via 302 using, for example, ALD, CVD, a wet coating process, other suitable techniques, or any combination thereof. The selective deposition causes the metal cap to not be formed on the dielectric layer 300. As a result, the metal cap 303 has a bottom surface completely disposed on a top surface of the metal via 302. In accordance with some embodiments, the metal cap 303 is formed under a process temperature ranging from room temperature to about 400° C. In accordance with some embodiments, the top surfaces of the metal via 302 and the dielectric layer 300 are formed to be coplanar (e.g., using a chemical-mechanical planarization (CMP) process), so the metal cap 303 is higher than the dielectric layer 300 in its entirety. In accordance with some embodiments, the metal via 302 is formed to be recessed from the dielectric layer 300, so the bottom surface of the metal cap 303 is lower than the top surface of the dielectric layer 300.

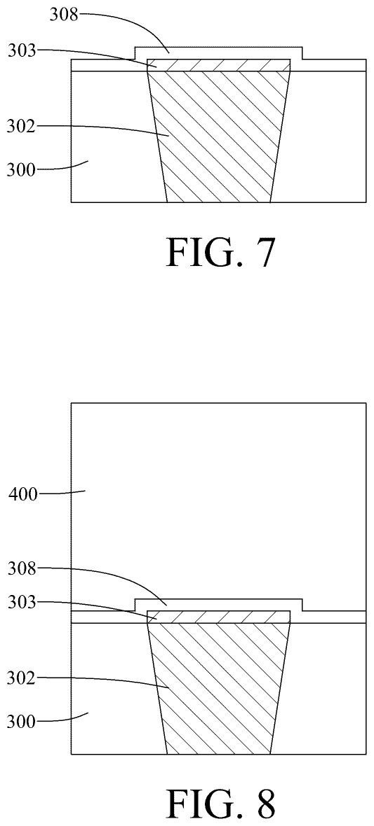

Referring to FIGS. 4 and 7, in step S03, an etch stop layer 308 is conformally deposited over the dielectric layer 300 and the metal cap 303. In accordance with some embodiments, the etch stop layer 308 may be formed using, for example, PVD, CVD, PECVD, ALD, other suitable deposition techniques, or any combination thereof.

Referring to FIGS. 4 and 8, in step S04, a dielectric layer 400 is deposited over the etch stop layer 308. In accordance with some embodiments, the dielectric layer 400 may be formed using, for example, PVD, CVD, PECVD, other suitable techniques, or any combination thereof.

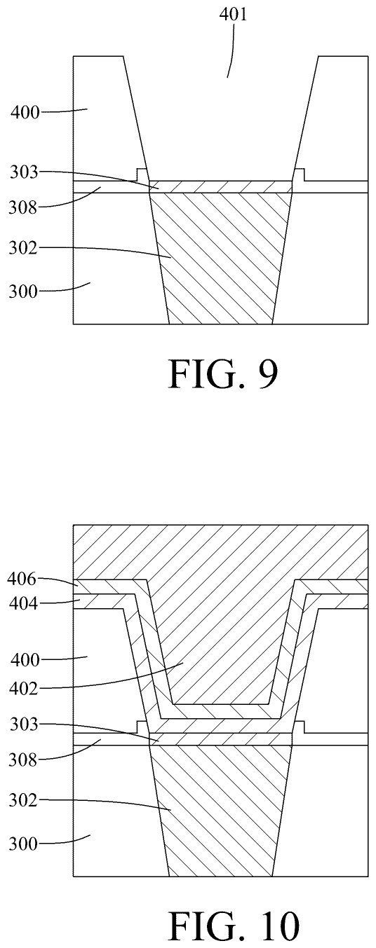

Referring to FIGS. 4 and 9, in step S05, the dielectric layer 400 and the etch stop layer 308 are patterned and etched through, for example, a lithography process, thereby forming a trench 401 to reveal the metal cap 303.

Referring to FIGS. 4 and 10, in step S06, a conductive barrier layer 404 is conformally formed over the dielectric layer 400 and the metal cap 303, a conductive liner layer 406 is conformally formed over the conductive barrier layer 404, and a metal layer 402 is deposited to fill the trench 401 (see FIG. 9). Accordingly, the metal cap 303 is disposed between the conductive barrier layer 404 and the metal via 302, thereby preventing direct contact therebetween. Then, a planarization process (e.g., a CMP process) may be performed to remove excessive portions of the metal layer 402, the conductive barrier layer 404 and the conductive liner layer 406, thereby forming the structure as shown in FIGS. 2 and 3. In accordance with some embodiments, each of the conductive barrier layer 404, the conductive liner layer 406 and the metal layer 402 may be deposited using, for example, PVD, CVD, PECVD, ALD, other suitable deposition techniques, or any combination thereof.

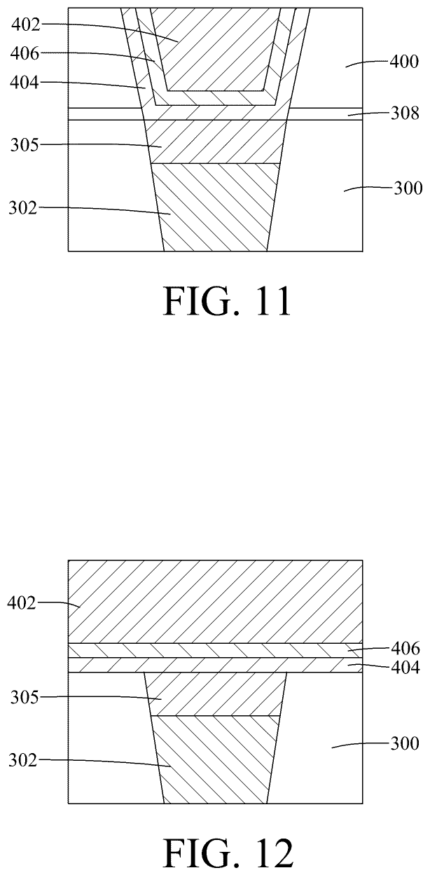

FIGS. 11 and 12 are sectional views respectively illustrating an X-cut section and a Y-cut section of an interconnection structure in accordance with a third embodiment, which is similar to the second embodiment, where the metal via 302 is different from the metal line 402 in terms of materials, and includes, for example, Mo, Ru, MoW, other suitable materials (e.g., metals, alloys, etc.), or any combination thereof. In the third embodiment, instead of the metal cap 303 (see FIGS. 2 and 3), a metal plug 305 is formed on top of the metal via 302, has a bottom surface completely disposed on the metal via 302, and is configured to separate the metal via 302 from the conductive barrier layer 404, thereby preventing formation of metal nitride during subsequent processes when the conductive barrier layer 404 includes nitrogen (e.g., TaN, TiN, and so on). In practice, the metal plug 305 would be made thicker than the metal cap 303, so a material used to form the metal plug 305 would be selected to have a relatively low resistivity. In accordance with some embodiments, the metal plug 305 has a resistivity smaller than a resistivity of a metal nitride material that includes a metal element which is also included in the metal via 302. Therefore, the overall resistance between the metal line 402 and the metal via 302 will equal a sum of resistances of the conductive liner layer 406, the conductive barrier layer 404, an interface between the conductive barrier layer 404 and the metal plug 305, and the metal plug 305, which would be smaller than the case when metal nitride is formed at an interface between the conductive barrier layer 404 and the metal via 302 due to a direct contact therebetween. In accordance with some embodiments, the metal plug 305 is thinner than the metal via 302, and may have a thickness in a range from about 30 angstroms to about 100 nanometers, thereby effectively separating the metal via 302 from the conductive barrier layer 404, while maintaining low resistance between the metal line 402 and the metal via 302. In accordance with some embodiments, the metal plug 305 may include, for example, Cu, CuZn, CuAl, other suitable materials (e.g., metals, alloys, etc.), or any combination thereof. These materials are not prone to react with nitrogen in the conductive barrier layer 404 to form metal nitride under the temperatures of the subsequent processes, usually lower than 400° C. In the illustrative embodiment, the metal plug 305 is surrounded by the dielectric layer 300, and has a top surface coplanar with the top surface of the dielectric layer 300. Accordingly, the top surface of the metal via 302 is lower than the top surface of the dielectric layer 300.

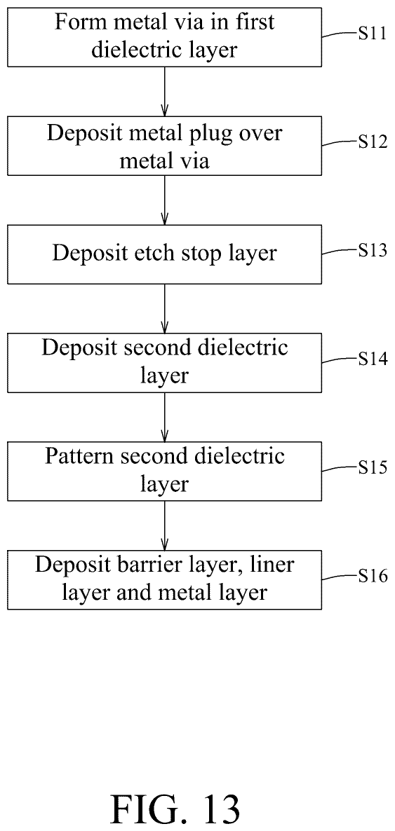

FIG. 13 is a flow chart illustrating a method for fabricating the interconnection structure in accordance with the third embodiment.

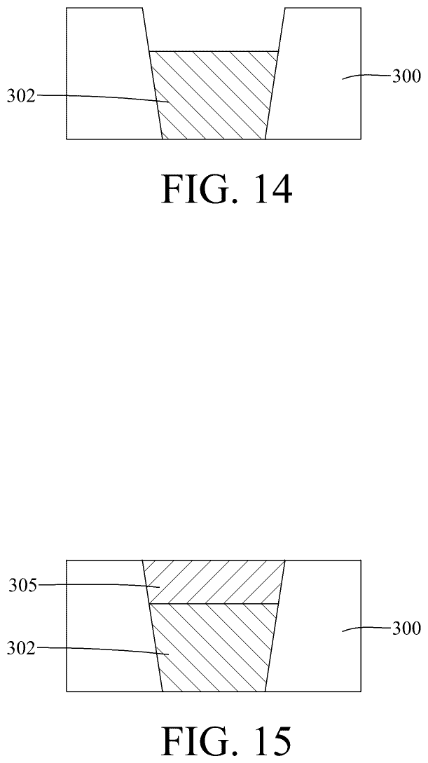

Referring to FIGS. 13 and 14, in step S11, a dielectric layer 300 and a metal via 302 are formed over a semiconductor substrate (not shown), where the dielectric layer 300 surrounds the metal via 302, and the metal via 302 is thinner than the dielectric layer 300. In accordance with some embodiments, the metal via 302 may be connected to a conductive component (e.g., the metal line 202 or the conductive cap layer 207 in FIG. 1) underlying the dielectric layer 300, and extend in an upward direction. In accordance with some embodiments, the metal via 302 may be formed using, for example, a single damascene process, a metal-first process, other suitable processes, or any combination thereof. In accordance with some embodiments, the dielectric layer 300 is first deposited, and is then patterned to form a via hole, followed by depositing a metal layer to form the metal via 302 in such a way (e.g., controlled by deposition time or by a number of deposition cycles) that the via hole is partially filled by the metal via 302 (i.e., the metal via 302 fills a lower portion of the via hole, while an upper portion of the via hole remains unfilled). In accordance with some embodiments, the metal via 302 may be deposited using, for example, CVD, ALD, PVD, ECP, electroless plating, other suitable techniques, or any combination thereof. In accordance with some embodiments, the metal via 302 is formed under a process temperature ranging from room temperature to about 400° C. In accordance with some embodiments, the dielectric layer 300 may be formed using, for example, PVD, CVD, PECVD, other suitable techniques, or any combination thereof.

Referring to FIGS. 13 and 15, in step S12, a metal plug 305 is formed over the metal via 302 and in the via hole using, for example, bottom-up CVD, ALD, ECP, electroless plating, other suitable techniques, or any combination thereof, so that the metal plug 305 cooperates with the metal via 302 to fill the via hole. In accordance with some embodiment, the metal plug 305 is selectively formed on the metal via 302, which causes the metal plug 305 to not be formed on the dielectric layer 300. In accordance with some embodiments, a metal layer is deposited in the via hole and over the dielectric layer 300, which is followed by a planarization process, thereby forming the metal plug 305 that has a top surface coplanar with a top surface of the dielectric layer 300. In accordance with some embodiments, the metal plug 305 is formed under a process temperature ranging from room temperature to about 400° C.

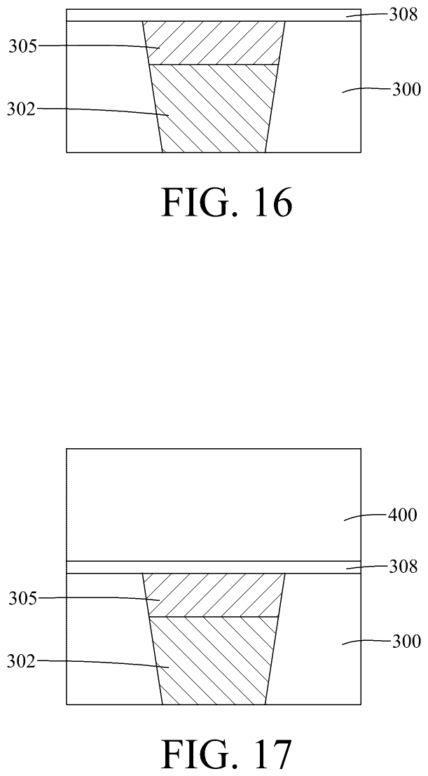

Referring to FIGS. 13 and 16, in step S13, an etch stop layer 308 is conformally deposited over the dielectric layer 300 and the metal plug 305. In accordance with some embodiments, the etch stop layer 308 may be formed using, for example, PVD, CVD, PECVD, ALD, other suitable deposition techniques, or any combination thereof.

Referring to FIGS. 13 and 17, in step S14, a dielectric layer 400 is deposited over the etch stop layer 308. In accordance with some embodiments, the dielectric layer 400 may be formed using, for example, PVD, CVD, PECVD, other suitable techniques, or any combination thereof.

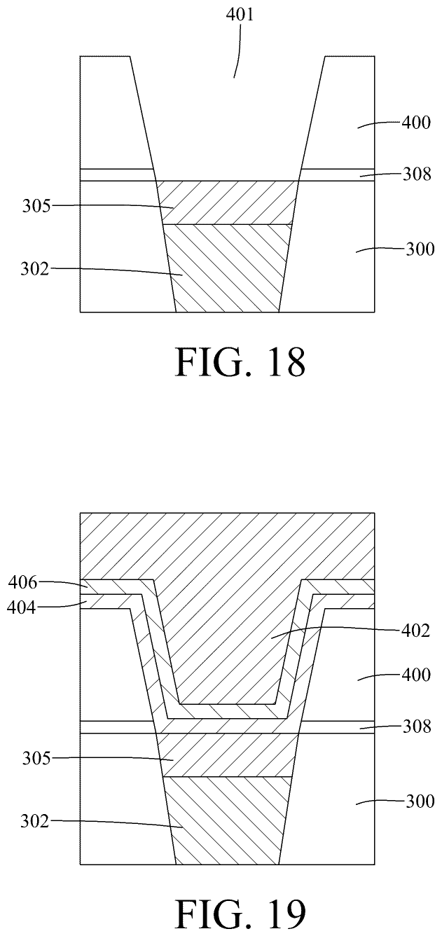

Referring to FIGS. 13 and 18, in step S15, the dielectric layer 400 and the etch stop layer 308 are patterned and etched through, for example, a lithography process, thereby forming a trench 401 to reveal the metal plug 305.

Referring to FIGS. 13 and 19, in step S16, a conductive barrier layer 404 is conformally formed over the dielectric layer 400 and the metal plug 305, a conductive liner layer 406 is conformally formed over the conductive barrier layer 404, and a metal layer 402 is deposited to fill the trench 401 (see FIG. 18). Accordingly, the metal plug 305 is disposed between the conductive barrier layer 404 and the metal via 302, thereby preventing a direct contact therebetween. Then, a planarization process (e.g., a CMP process) may be performed to remove excessive portions of the metal layer 402, the conductive barrier layer 404 and the conductive liner layer 406, thereby forming the structure as shown in FIGS. 11 and 12.

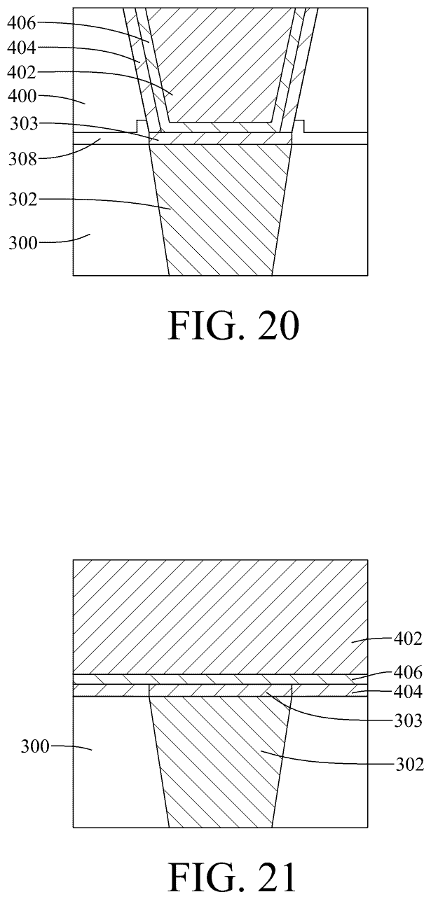

FIGS. 20 and 21 are sectional views respectively illustrating an X-cut section and a Y-cut section of an interconnection structure in accordance with a fourth embodiment, which is similar to the second embodiment. In the fourth embodiment, the conductive barrier layer 404 is disposed between the metal line 402 and the dielectric layer 400, but is not disposed between the metal line 402 and the metal cap 303, thereby reducing the resistance between the metal line 402 and the metal via 302. The metal cap 303 is disposed to separate the metal via 302 from the conductive liner layer 406, thereby preventing intermixing of the conductive liner layer 406 and the metal via 302 (e.g., RuCo may be formed when the metal via 302 including Ru and the metal liner layer 406 including Co are intermixed), which may lead to increased resistance. In accordance with some embodiments, the metal cap 303 has a resistivity smaller than an alloy that includes a metal element which is also included in the metal via 302, and another metal element which is also included in the conductive liner layer 406, so the overall resistance between the metal line 402 and the metal via 302 can be improved. In accordance with some embodiments, the metal cap 303 may include, for example, W, Cu, CuAl, CuZn, other suitable materials (e.g., metals, alloys, etc.), or any combination thereof. These materials are not prone to mix with metal elements in the conductive liner layer 406 to form an alloy with relatively high resistance under the temperatures of the subsequent processes, usually lower than 400° C. In accordance with some embodiments, the metal cap 303 is thinner than the metal via 302, and may have a thickness in a range from about 5 angstroms to about 30 angstroms, thereby effectively separating the metal via 302 from the conductive liner layer 406, while minimizing the increase of resistance resulting from the metal cap 303.

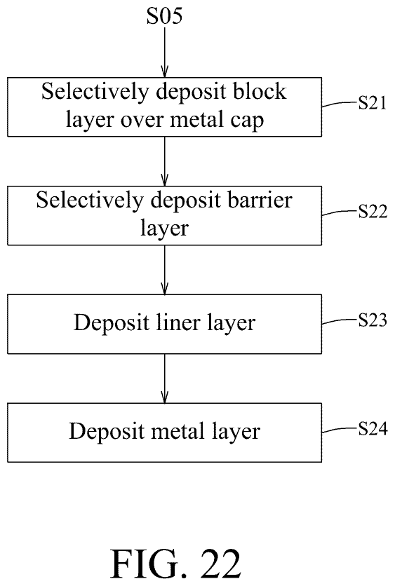

FIG. 22 is a flow chart illustrating a method for fabricating the interconnection structure in accordance with the fourth embodiment. The flow includes aforesaid steps S01 through S05 as introduced in FIG. 4, and steps S21 through S24 that follow step S05. Details of steps S01 through S05 are not repeated herein for the sake of brevity.

Referring to FIGS. 22 and 23, in step S21 that follows step S05, a block layer (or inhibitor layer) 403 is selectively deposited onto the metal cap 303 using, for example, CVD, ALD, spin coating, immersion, other suitable techniques, or any combination thereof. The selective deposition causes the block layer 403 to not be formed on the dielectric layer 400. In accordance with some embodiments, the block layer 403 uses a material that tends to form on metal surfaces rather than dielectric surfaces, and may include small molecules such as N-containing organic compounds, macro molecules such as polymers with anchoring groups, other suitable materials, or any combination thereof. In accordance with some embodiments, the block layer 403 may have a thickness in a range from about 1 angstrom to about 1 micrometer, depending on the targeted structure.

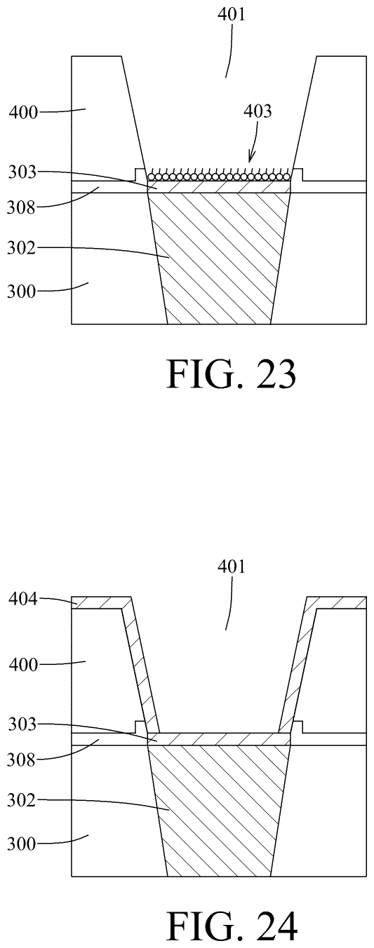

Referring to FIGS. 22 and 24, in step S22, a conductive barrier layer 404 is conformally deposited on the dielectric layer 400, but not on the metal cap 303 because the block layer 403 (see FIG. 23) formed in step S21 induces selective deposition that causes the conductive barrier layer 404 to not be formed on the metal cap 303. In accordance with some embodiments, the block layer 403 may be removed during the deposition of the conductive barrier layer 404. In accordance with some embodiments, the block layer 403 may be removed after the deposition of the conductive barrier layer 404. In accordance with some embodiments, the block layer 403 may be removed using, for example, a thermal process, electrical-assisted desorption, plasma bombardment, other suitable techniques, or any combination thereof.

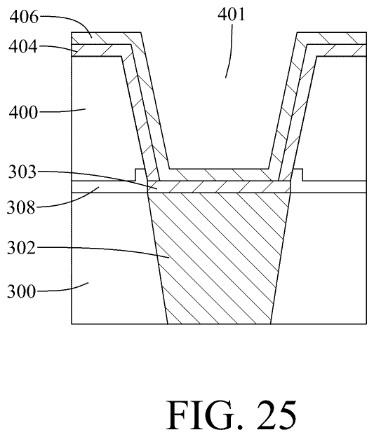

Referring to FIGS. 22 and 25, in step S23, a conductive liner layer 406 is conformally deposited on the conductive barrier layer 404 and the metal cap 303, so the metal cap 303 is disposed between the conductive liner layer 406 and the metal via 302. Then, in step S24, a metal layer is deposited to fill the trench 401, which is followed by a planarization process, thereby forming the metal line 402 as shown in FIGS. 20 and 21.

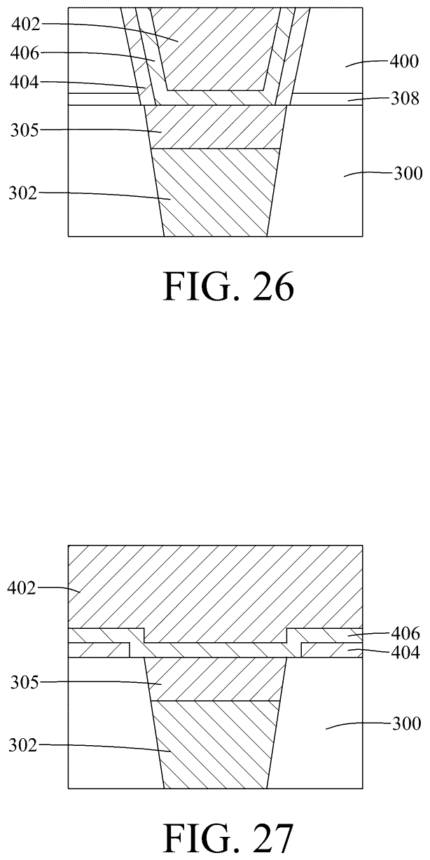

FIGS. 26 and 27 are sectional views respectively illustrating an X-cut section and a Y-cut section of an interconnection structure in accordance with a fifth embodiment, which is similar to the fourth embodiment. In the fifth embodiment, instead of the metal cap 303 (see FIGS. 20 and 21), a metal plug 305 is formed between the metal via 302 and the conductive liner layer 406. The conductive barrier layer 404 is disposed between the metal line 402 and the dielectric layer 400, but is not disposed between the metal line 402 and the metal plug 305, thereby reducing the resistance between the metal line 402 and the metal via 302. The metal plug 305 is disposed to separate the metal via 302 from the conductive liner layer 406, thereby preventing intermixing of the conductive liner layer 406 and the metal via 302. In accordance with some embodiments, the metal plug 305 has a resistivity smaller than an alloy that includes a metal element which is also included in the metal via 302, and another metal element which is also included in the conductive liner layer 406, so the overall resistance between the metal line 402 and the metal via 302 can be improved. In accordance with some embodiments, the metal plug 30 may include, for example, Cu, CuAl, CuZn, other suitable materials (e.g., metals, alloys, etc.), or any combination thereof. In accordance with some embodiments, the metal plug 305 is thinner than the metal via 302, and may have a thickness in a range from about 30 angstroms to about 100 nanometers, thereby effectively separating the metal via 302 from the conductive liner layer 406, while maintaining low resistance between the metal line 402 and the metal via 302.

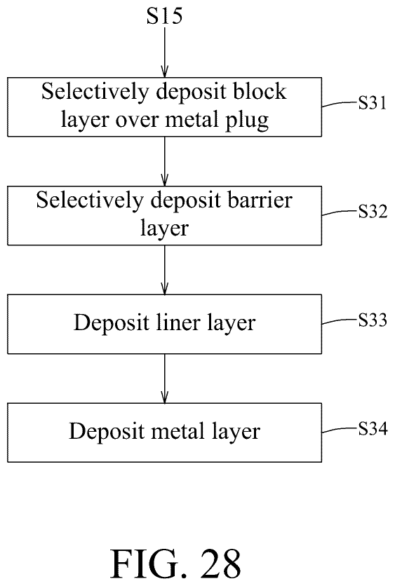

FIG. 28 is a flow chart illustrating a method for fabricating the interconnection structure in accordance with the fifth embodiment. The flow includes aforesaid steps S11 through S15 as introduced in FIG. 13, and steps S31 through S34 that follow step S15. Details of steps S11 through S15 are not repeated herein for the sake of brevity.

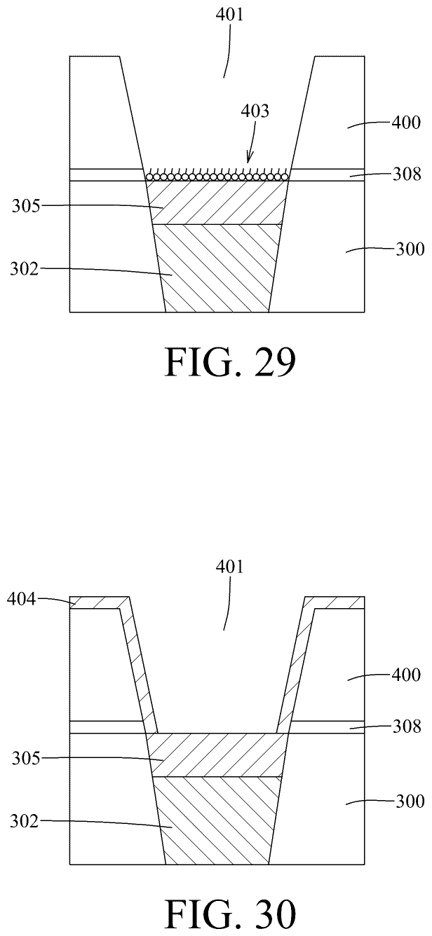

Referring to FIGS. 28 and 29, in step S31 that follows step S15, a block layer (or inhibitor layer) 403 is selectively deposited onto the metal plug 305 using, for example, CVD, ALD, spin coating, immersion, other suitable techniques, or any combination thereof. The selective deposition causes the block layer 403 to not be formed on the dielectric layer 400. In accordance with some embodiments, the block layer 403 may include small molecules such as N-containing organic compounds, macro molecules such as polymers with anchoring groups, other suitable materials, or any combination thereof. In accordance with some embodiments, the block layer 403 may have a thickness in a range from about 1 angstrom to about 1 micrometer, depending on the targeted structure.

Referring to FIGS. 28 and 30, in step S32, a conductive barrier layer 404 is conformally deposited on the dielectric layer 400, but not on the metal plug 305 because the block layer 403 (see FIG. 30) formed in step S31 induces selective deposition that causes the conductive barrier layer 404 to not be formed on the metal plug 305. In accordance with some embodiments, the block layer 403 may be removed during the deposition of the conductive barrier layer 404. In accordance with some embodiments, the block layer 403 may be removed after the deposition of the conductive barrier layer 404. In accordance with some embodiments, the block layer 403 may be removed using, for example, a thermal process, electrical-assisted desorption, plasma bombardment, other suitable techniques, or any combination thereof.

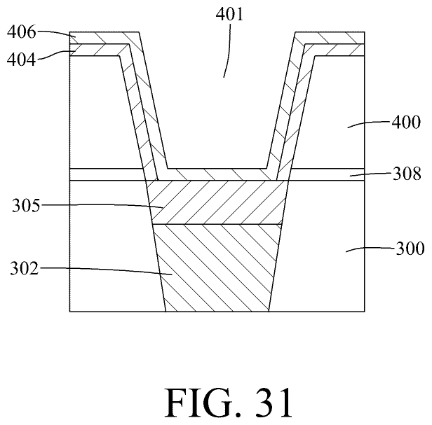

Referring to FIGS. 28 and 31, in step S33, a conductive liner layer 406 is conformally deposited on the conductive barrier layer 404 and the metal plug 305, so the metal plug 305 is disposed between the conductive liner layer 406 and the metal via 302. Then, in step S34, a metal layer is deposited to fill the trench 401, which is followed by a planarization process, thereby forming the metal line 402 as shown in FIGS. 26 and 27.

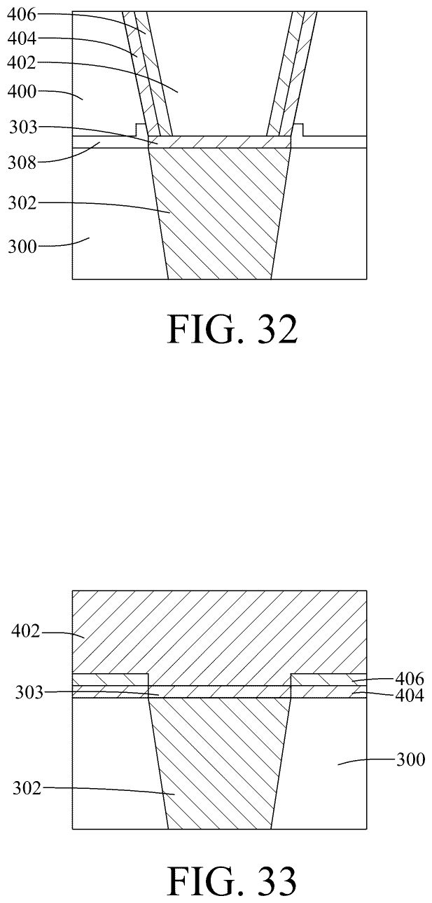

FIGS. 32 and 33 are sectional views respectively illustrating an X-cut section and a Y-cut section of an interconnection structure in accordance with a sixth embodiment, which is similar to the fourth embodiment. In the sixth embodiment, both the conductive barrier layer 404 and the conductive liner layer 406 are disposed between the metal line 402 and the dielectric layer 400, but are not disposed between the metal line 402 and the metal cap 303, thereby further reducing the resistance between the metal line 402 and the metal via 302. The metal cap 303 separates the metal via 302 from the conductive barrier layer 404 and the conductive liner layer 406 that are formed over the sidewall of the dielectric layer 400, thereby preventing formation of metal nitride due to the contact between the conductive barrier layer 404 and the metal via 302, and/or intermixing of metal between the conductive liner layer 406 and the metal via 302. In accordance with some embodiments, the metal cap 303 may include, for example, W, Cu, CuAl, CuZn, other suitable materials (e.g., metals, alloys, etc.), or any combination thereof. In accordance with some embodiments, the metal cap 303 is thinner than the metal via 302, and may have a thickness in a range from about 5 angstroms to about 30 angstroms.

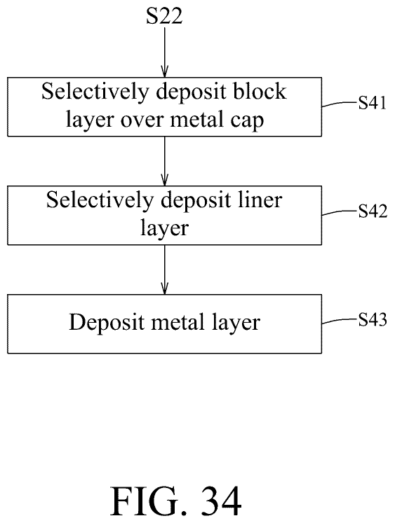

FIG. 34 is a flow chart illustrating a method for fabricating the interconnection structure in accordance with the sixth embodiment. The flow includes aforesaid steps S01 through S05 as introduced in FIG. 4, steps S21 and S22 as introduced in FIG. 22, and steps S41 through S43 that follow step S22. Details of steps S01 through S05 and steps S21 and S22 are not repeated herein for the sake of brevity.

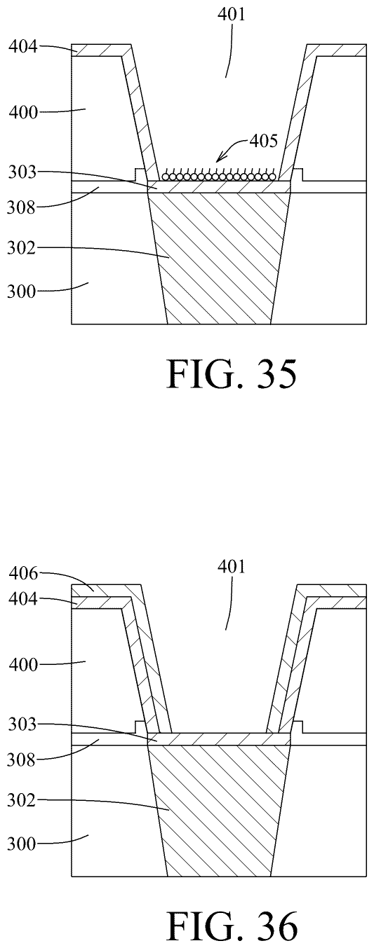

Referring to FIGS. 34 and 35, in step S41 that follows step S22, another block layer (or inhibitor layer) 405 is selectively deposited onto the metal cap 303 using, for example, CVD, ALD, spin coating, immersion, other suitable techniques, or any combination thereof. The selective deposition causes the block layer 405 to not be formed on the conductive barrier layer 404. In accordance with some embodiments, the block layer 405 uses a material that tends to form on the material forming the metal cap 303 rather than the material forming the conductive barrier layer 404, and may include small molecules such as N-containing organic compounds, macro molecules such as polymers with anchoring groups, other suitable materials, or any combination thereof. The block layer 405 may include either the same material as the block layer 403 (used in step S21, see FIG. 23) or different materials. The block layer 405 may have a thickness in a range from about 1 angstrom to about 1 micrometer, depending on the targeted structure.

Referring to FIGS. 34 and 36, in step S42, a conductive liner layer 406 is conformally deposited on the conductive barrier layer 404, but not on the metal cap 303 because the block layer 405 (see FIG. 35) formed in step S41 induces selective deposition that causes the conductive liner layer 406 to not be formed on the metal cap 303. In accordance with some embodiments, the block layer 405 may be removed during the deposition of the conductive liner layer 406. In accordance with some embodiments, the block layer 405 may be removed after the deposition of the conductive liner layer 406. In accordance with some embodiments, the block layer 405 may be removed using, for example, a thermal process, electrical-assisted desorption, plasma bombardment, other suitable techniques, or any combination thereof. In accordance with some embodiments, the block layer 403 is not exhausted during the deposition of the conductive barrier layer 404 (i.e., the block layer 403 remains on the metal cap 303 after step S22), step S41 may be omitted, and the conductive liner layer 406 can be directly deposited in step S42 to form the structure as shown in FIG. 36. Then, in step S43 that follows step S42, a metal layer is deposited to fill the trench 401, which is followed by a planarization process, thereby forming the metal line 402 as shown in FIGS. 32 and 33. In accordance with some embodiments, a metal plug can be formed in place of the metal cap 303 in the sixth embodiment using the aforesaid method, and this disclosure is not limited in this respect.

In accordance with some embodiments, a method is provided for fabricating an interconnection structure. In one step, a first metal feature and a first dielectric layer are formed on a semiconductor substrate, and the first dielectric layer surrounds the first metal feature. In one step, a second metal feature is formed to be aligned with and cover the first metal feature, and the second metal feature is different from the first metal feature in terms of materials. In one step, a second dielectric layer is deposited over the first dielectric layer and the second metal feature. In one step, a trench is formed in the second dielectric layer to reveal the second metal feature. In one step, a metal line is formed in the trench.

In accordance with some embodiments, the second metal feature is thinner than the first metal feature.

In accordance with some embodiments, the first metal feature is different from the metal line in terms of materials.

In accordance with some embodiments, in one step, a conductive barrier layer is formed on a sidewall of the trench before the metal line is formed. The second metal feature is different from the conductive barrier layer in terms of materials.

In accordance with some embodiments, the second metal feature has a resistivity smaller than a resistivity of a metal nitride material that includes a metal element which is included in the first metal feature.

In accordance with some embodiments, the second metal feature has a bottom surface completely formed on a top surface of the first metal feature.

In accordance with some embodiments, the conductive barrier layer includes a metal nitride material, and has a portion disposed between the second metal feature and the metal line.

In accordance with some embodiments, the forming of the conductive barrier layer is performed using selective deposition that causes the conductive barrier layer to not be formed on the second metal feature.

In accordance with some embodiments, in one step, a conductive liner layer is formed on the conductive barrier layer before the metal line is formed. The second metal feature is different from the conductive liner layer in terms of materials.

In accordance with some embodiments, the forming of the conductive barrier layer is performed using selective deposition that causes the conductive barrier layer to not be formed on the second metal feature. The forming of the conductive liner layer is performed using selective deposition that causes the conductive liner layer to not be formed on the second metal feature.

In accordance with some embodiments, the second metal feature has a resistivity smaller than a resistivity of an alloy that includes a metal element which is included in the first metal feature, and another metal element which is included in the conductive liner layer.

In accordance with some embodiments, the second metal feature is selectively deposited over the first metal feature.

In accordance with some embodiments, the first metal feature includes one of Mo and Ru, and the second metal features includes one of W, Cu, CuAl and CuZn.

In accordance with some embodiments, the forming of the first metal feature and the first dielectric layer includes several actions. In one action, the first dielectric layer is deposited over the semiconductor substrate. In one action, a via hole is formed in the first dielectric layer. In one action, the first metal feature is formed in the via hole in such a way that the via hole is partially filled by the first metal feature. The second metal feature is a metal plug formed in the via hole, and cooperating with the first metal feature to fill the via hole.

In accordance with some embodiments, the first metal feature includes one of Mo and Ru, and the second metal features includes one of Cu and CuZn.

In accordance with some embodiments, a method is provided for fabricating an interconnection structure. In one step, a metal via and a first dielectric layer are formed on a semiconductor substrate, where the first dielectric layer surrounds the metal via, and the metal via extends in an upward direction from a conductive component underlying the first dielectric layer. In one step, a metal feature is formed over the metal via, where the metal feature is different from the metal via in terms of materials, and has a bottom surface disposed completely on a top surface of the metal via. In one step, a metal line is formed over the first dielectric layer and the metal feature, where the metal line is spaced apart from the metal via, is electrically connected to the metal via through the metal feature, and extends in a lateral direction transverse to the upward direction.

In accordance with some embodiments, the method further includes some steps as follows before the metal line is formed. In one step, a second dielectric layer is formed over the first dielectric layer and the metal feature. In one step, a trench is formed in the second dielectric layer to reveal the metal feature. In one step, a conductive barrier layer is formed conformally in the trench. The metal line is formed in the trench and over the conductive barrier layer, thereby causing the conductive barrier layer to be disposed between the metal feature and the metal line. The conductive barrier layer includes nitrogen, and the metal feature has a resistivity smaller than a resistivity of a metal nitride material that includes a metal element which is included in the metal via.

In accordance with some embodiments, the metal via includes one of molybdenum and ruthenium, and the resistivity of the metal feature is smaller than each of molybdenum nitride and ruthenium nitride.

In accordance with some embodiments, the metal feature is selectively formed on the metal via.

In accordance with some embodiments, an interconnection structure is provided to include a first dielectric layer disposed on a semiconductor substrate, a first metal feature disposed in the first dielectric layer and extending upward, a second dielectric layer disposed over the first dielectric layer, a metal line disposed in the second dielectric layer and over the first metal feature, and a second metal feature disposed between the first metal feature and the metal line. The metal line is electrically connected to the first metal feature through the second metal feature. The second metal feature is different from the first metal feature in terms of materials.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for fabricating an interconnection structure, comprising:
forming a first metal feature and a first dielectric layer on a semiconductor substrate, the first dielectric layer surrounding the first metal feature;
forming a second metal feature aligned with and covering the first metal feature, the second metal feature being different from the first metal feature in terms of materials;
depositing a second dielectric layer over the first dielectric layer and the second metal feature;
forming a trench in the second dielectric layer to reveal the second metal feature; and
forming a metal line in the trench.

2. The method according to claim 1, wherein the second metal feature is thinner than the first metal feature.

3. The method according to claim 1, wherein the first metal feature is different from the metal line in terms of materials.

4. The method according to claim 1, further comprising, before forming the metal line:
forming a conductive barrier layer on a sidewall of the trench,
wherein the second metal feature is different from the conductive barrier layer in terms of materials.

5. The method according to claim 4, wherein the second metal feature has a resistivity smaller than a resistivity of a metal nitride material that includes a metal element which is included in the first metal feature.

6. The method according to claim 5, wherein the second metal feature has a bottom surface completely formed on a top surface of the first metal feature.

7. The method according to claim 5, wherein the conductive barrier layer includes a metal nitride material, and has a portion disposed between the second metal feature and the metal line.

8. The method according to claim 4, wherein the forming of the conductive barrier layer is performed using selective deposition that causes the conductive barrier layer to not be formed on the second metal feature.

9. The method according to claim 4, further comprising, before forming the metal line:
forming a conductive liner layer on the conductive barrier layer;
wherein the second metal feature is different from the conductive liner layer in terms of materials.

10. The method according to claim 9, wherein the forming of the conductive barrier layer is performed using selective deposition that causes the conductive barrier layer to not be formed on the second metal feature; and
wherein the forming of the conductive liner layer is performed using selective deposition that causes the conductive liner layer to not be formed on the second metal feature.

11. The method according to claim 10, wherein the second metal feature has a resistivity smaller than a resistivity of an alloy that includes a metal element which is included in the first metal feature, and another metal element which is included in the conductive liner layer.

12. The method according to claim 1, wherein the second metal feature is selectively deposited over the first metal feature.

13. The method according to claim 12, wherein the first metal feature includes one of Mo and Ru, and the second metal features includes one of W, Cu, CuAl and CuZn.

14. The method according to claim 1, wherein the forming of the first metal feature and the first dielectric layer includes:
depositing the first dielectric layer over the semiconductor substrate;
forming a via hole in the first dielectric layer; and
forming the first metal feature in the via hole in such a way that the via hole is partially filled by the first metal feature; and
wherein the second metal feature is a metal plug formed in the via hole, and cooperating with the first metal feature to fill the via hole.

15. The method according to claim 14, wherein the first metal feature includes one of Mo and Ru, and the second metal features includes one of Cu and CuZn.

16. A method for fabricating an interconnection structure, comprising:
forming a metal via and a first dielectric layer on a semiconductor substrate, where the first dielectric layer surrounds the metal via, and the metal via extends in an upward direction from a conductive component underlying the first dielectric layer;
forming a metal feature over the metal via, where the metal feature is different from the metal via in terms of materials, and has a bottom surface disposed completely on a top surface of the metal via; and
forming a metal line over the first dielectric layer and the metal feature, where the metal line is spaced apart from the metal via, is electrically connected to the metal via through the metal feature, and extends in a lateral direction transverse to the upward direction.

17. The method according to claim 16, further comprising, before forming the metal line:
forming a second dielectric layer over the first dielectric layer and the metal feature;
forming a trench in the second dielectric layer to reveal the metal feature; and
forming a conductive barrier layer conformally in the trench;
wherein the metal line is formed in the trench and over the conductive barrier layer, thereby causing the conductive barrier layer to be disposed between the metal feature and the metal line; and
wherein the conductive barrier layer includes nitrogen, and the metal feature has a resistivity smaller than a resistivity of a metal nitride material that includes a metal element which is included in the metal via.

18. The method according to claim 17, wherein the metal via includes one of molybdenum and ruthenium, and the resistivity of the metal feature is smaller than each of molybdenum nitride and ruthenium nitride.

19. The method according to claim 16, wherein the metal feature is selectively formed on the metal via.

20. An interconnection structure, comprising:
a first dielectric layer disposed on a semiconductor substrate;
a first metal feature disposed in the first dielectric layer and extending upward;
a second dielectric layer disposed over the first dielectric layer;
a metal line disposed in the second dielectric layer and over the first metal feature; and
a second metal feature disposed between the first metal feature and the metal line;
wherein the metal line is electrically connected to the first metal feature through the second metal feature; and
wherein the second metal feature is different from the first metal feature in terms of materials.
